(19) United States
(12) Patent Application Publication
(10) Pub. No.: US 2026/0347610 A1
(43) Pub. Date: Nov. 5, 2026

(54) METHOD FOR MANUFACTURING ENCAPSULANT COMPOSITION, ENCAPSULANT COMPOSITION, AND APPARATUS FOR MANUFACTURING ENCAPSULANT COMPOSITION

(71) Applicant: DOW SILICONES CORPORATION, Midland, MI (US)

(72) Inventors: Kwangjin LEE, Chungcheongbuk-Do (KR); Gregory THEUNICK, Midland, MI (US)

(21) Appl. No.: 19/485,921

(22) PCT Filed: Apr. 12, 2024
(86) PCT No.: PCT/US2024/024335

§ 371 Date: Nov. 19, 2025

Related U.S. Application Data
(60) Provisional application No. 63/469,881, filed on May 31, 2023.

(51) Int. Cl. C08L 83/06; C08K 11/00; H10K 50/844; H10K 85/40

(52) U.S. Cl. CPC C08L 83/06; C08K 11/00; H10K 50/844; H10K 85/40; C08K 2201/019; C08L 2205/02

(57) ABSTRACT

The present disclosure relates to a method for manufacturing an encapsulant composition, an encapsulant composition, and an apparatus for manufacturing an encapsulant composition. According to the apparatus and manufacturing method according to the present disclosure, in a situation where requirements for low moisture content of display manufacturing materials are becoming more common and strengthened as display technology develops, it is possible to solve the problems of contamination and complex process concerns inherent in conventional drying technologies.

### CROSS-REFERENCE TO RELATED APPLICATIONS

This application claims priority to and all advantages of U.S. Application No. 63/469,881 filed on 31 May 2023, the content of which is incorporated herein by reference in its entirety.

### TECHNICAL FIELD

The present disclosure relates to a method for manufacturing an encapsulant composition, an encapsulant composition, and an apparatus for manufacturing an encapsulant composition.

### BACKGROUND ART

Sensitivity to moisture is an important problem with electronic devices. Typical electronic devices require humidity levels in a range of below 1,000 ppm and some require humidity levels in a range of below even 100 ppm to prevent premature degradation of device performance within specified operating or storage life.

Thin film encapsulation (TFE) technology is a technology used to protect organic electroluminescent device (OLED) displays such as moisture and oxygen. It is possible to seal the OLED from the environment by applying a thin barrier material over the OLED layer.

Acrylate-based resins, silicone-based resins, epoxy-based resins, etc., are generally used as materials for an encapsulant composition used for thin film encapsulation of an OLED, and the encapsulant composition is supplied to a thin film encapsulation process. It is common to sufficiently dry beforehand to have a moisture content within a certain range.

The method using a gravity method, coalescing method, and centrifugal separator for separation when the water phase of the encapsulant composition material of the OLED is mainly dissolved free water derived from moisture in the air, is not appropriate. In addition, drying technologies for storage such as headspace dehumidification, active ventilation, and dry breathers may also be excluded.

When the encapsulant composition includes a photoinitiator, it can be easily activated not only by ultraviolet rays but also by heat, and thus a heating process should be avoided. In the case of absorption/adsorption using a molecular sieve, pretreatment is mostly required for a high dehydration effect, and there is a problem in that the viscosity of the product increases due to chemical contamination.

Gas bubbling is the most promising dewatering method but is difficult to control. This technology uses an inert gas such as nitrogen to avoid contamination simply, but it is difficult to set up a stable production process because the moisture content result after drying is easily influenced by the atmosphere. The design of the drying apparatus must clearly demonstrate the water removal performance and must be able to control various variables related to water contamination.

International Patent Publication No. 2021/200668 discloses a composition for sealing an OLED including a (meth)acrylate-based polymerizable compound and photopolymerization initiator, and having a moisture content of 1 to 50 ppm. In addition, a method of dehydrating the composition by adding a separate drying agent or heating under reduced pressure is disclosed. However, the above document does not suggest a method for controlling the moisture content of a composition for sealing an OLED including a silicone-based resin which has excellent thermal stability, chemical stability, flexibility, electrical insulation, etc., compared to acrylate-based resins.

Hence, there is a need to develop an encapsulant composition having a moisture content of 100 ppm or less as an encapsulant composition containing a silicone-based resin and a dehydration apparatus capable of preparing such an encapsulant composition.

### PRIOR ART DOCUMENTS

### Patent Documents

Patent Document 1: International Patent Publication No. 2021/200668

### SUMMARY OF INVENTION

### Technical Problem

An object of the present disclosure is to provide an encapsulant composition having a moisture content of 100 ppm or less, an apparatus for manufacturing the same, and a method for manufacturing the composition using the apparatus.

### Solution to Problem

In order to solve the aforementioned problem, the present disclosure provides a method for manufacturing an encapsulant composition having a moisture content of 100 ppm or less with use of an apparatus comprising: a drying vessel including therein a sparger being inserted into a liquid encapsulant composition pooled at a lower side of the drying vessel and sieve trays positioned above the pooled liquid encapsulant composition; an inert gas supply source supplying inert gas to the drying vessel; and a transfer tube including a first connection connected to an upper portion of the drying vessel and a second connection connected to a lower portion of the drying vessel, the method comprising: supplying the inert gas from the inert gas supply source through the sparger into the liquid encapsulant composition; sucking the liquid encapsulant composition in the drying vessel from the second connection and supplying the sucked liquid encapsulant composition to the first connection through the transfer tube; and returning the supplied liquid encapsulant composition from the first connection to the pooled encapsulant composition through the sieve trays.

In addition, the present disclosure provides an encapsulant composition comprising a silicone and silicone organic hybrid oligomers and a UV cure initiator or a heat cure catalyst, wherein the encapsulant composition has a moisture content of 100 ppm or less.

In addition, the present disclosure provides an encapsulant composition comprising a silicone and silicone organic hybrid oligomers and a UV cure initiator or a heat cure catalyst, wherein the encapsulant composition has a moisture content of 100 ppm or less, wherein the encapsulant composition is manufactured by the aforementioned method.

In addition, the present disclosure provides an apparatus for manufacturing an encapsulant composition having a moisture content of 100 ppm or less, the apparatus comprising: a drying vessel configured to pool a liquid encapsulant composition pooled at a lower side of the drying vessel; a sparger being inserted into the pooled liquid encapsulant composition; sieve trays positioned above the pooled liquid encapsulant composition; an inert gas supply source configured to supply the inert gas to the pooled liquid encapsulant composition in the drying vessel through the sparger; and a transfer tube including a first connection connected to an upper portion of the drying vessel and a second connection connected to a lower portion of the drying vessel, wherein the transfer tube is configured to suck the pooled liquid encapsulant composition via the second connection and supply the sucked liquid encapsulant composition to the first connection through the transfer tube, such that the supplied liquid encapsulant composition is returned to the pooled encapsulant composition from the first connection through the sieve trays.

### Effects of Invention

According to the present disclosure, in a situation where requirements for low moisture content of display manufacturing materials are becoming more common and strengthened as display technology develops, it is possible to solve the problems of contamination and complex process concerns inherent in conventional drying technologies.

### BRIEF DESCRIPTION OF THE DRAWING(S)

FIG. 1 is a diagram schematically illustrating the apparatus according to an embodiment of the present disclosure.

### DEFINITIONS

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

The use of “for example,” “e.g.,” “such as,” and “including” to list illustrative examples does not limit to only the listed examples. Thus, “for example” or “such as” means “for example, but not limited to” or “such as, but not limited to” and encompasses other similar or equivalent examples. The term “about” as used herein serves to reasonably encompass or describe minor variations in numerical values measured by instrumental analysis or as a result of sample handling. Such minor variations may be in the order of ±0-25, ±0-10, ±0-5, or ±0-2.5, % of the numerical values. Further, the term “about” applies to both numerical values when associated with a range of values. Moreover, the term “about” may apply to numerical values even when not explicitly stated.

It is to be understood that the appended claims are not limited to express and particular compounds, compositions, or methods described in the detailed description, which may vary between particular embodiments which fall within the scope of the appended claims. With respect to any Markush groups relied upon herein for describing particular features or aspects of various embodiments, it is to be appreciated that different, special, and/or unexpected results may be obtained from each member of the respective Markush group independent from all other Markush members. Each member of a Markush group may be relied upon individually and or in combination and provides adequate support for specific embodiments within the scope of the appended claims.

It is also to be understood that any ranges and subranges relied upon in describing various embodiments of the present invention independently and collectively fall within the scope of the appended claims, and are understood to describe and contemplate all ranges including whole and/or fractional values therein, even if such values are not expressly written herein. One of skill in the art readily recognizes that the enumerated ranges and subranges sufficiently describe and enable various embodiments of the present invention, and such ranges and subranges may be further delineated into relevant halves, thirds, quarters, fifths, and so on. As just one example, a range “of from 0.1 to 0.9” may be further delineated into a lower third, i.e., from 0.1 to 0.3, a middle third, i.e., from 0.4 to 0.6, and an upper third, i.e., from 0.7 to 0.9, which individually and collectively are within the scope of the appended claims, and may be relied upon individually and/or collectively and provide adequate support for specific embodiments within the scope of the appended claims. In addition, with respect to the language which defines or modifies a range, such as “at least,” “greater than,” “less than,” “no more than,” and the like, it is to be understood that such language includes subranges and/or an upper or lower limit. As another example, a range of “at least 10” inherently includes a subrange of from at least 10 to 35, a subrange of from at least 10 to 25, a subrange of from 25 to 35, and so on, and each subrange may be relied upon individually and/or collectively and provides adequate support for specific embodiments within the scope of the appended claims. Finally, an individual number within a disclosed range may be relied upon and provides adequate support for specific embodiments within the scope of the appended claims. For example, a range “of from 1 to 9” includes various individual integers, such as 3, as well as individual numbers including a decimal point (or fraction), such as 4.1, which may be relied upon and provide adequate support for specific embodiments within the scope of the appended claims.

### DETAILED DESCRIPTION OF THE INVENTION

Hereinafter, the present disclosure is described in more detail. However, it is only for explanatory purposes only and the present disclosure should not be construed in any way to limit the scope of the present disclosure.

The present disclosure is related to a method for manufacturing an encapsulant composition having a moisture content of 100 ppm or less with use of an apparatus comprising: a drying vessel including therein a sparger being inserted into a liquid encapsulant composition pooled at a lower side of the drying vessel and sieve trays positioned above the pooled liquid encapsulant composition; an inert gas supply source supplying inert gas to the drying vessel; and a transfer tube including a first connection connected to an upper portion of the drying vessel and a second connection connected to a lower portion of the drying vessel, the method comprising: supplying the inert gas from the inert gas supply source through the sparger into the liquid encapsulant composition; sucking the liquid encapsulant composition in the drying vessel from the second connection and supplying the sucked liquid encapsulant composition to the first connection through the transfer tube; and returning the supplied liquid encapsulant composition from the first connection to the pooled encapsulant composition through the sieve trays.

According to the manufacturing method of the present disclosure, an encapsulant composition having a moisture content of 100 ppm or less is provided.

When an encapsulant composition, for example, a composition for sealing an OLED contains an organic solvent such as toluene, etc., or dehydrates a composition using an additive such as a desiccant, the dehydrated composition contains residual organic solvents or additives. As a material for manufacturing an OLED, there is a problem in that high purity of the product cannot be guaranteed. Furthermore, when the composition for sealing an OLED is dehydrated by heating at a high temperature, there is a problem in that the photopolymerization initiator included in the composition is activated by heat.

Accordingly, the present disclosure can provide an encapsulant composition that solves various problems while lowering the moisture content of the encapsulant composition to 100 ppm or less using a gas stripping apparatus using gas bubbling.

The encapsulant composition according to the present disclosure may include silicone and silicone organic hybrid oligomers and a UV cure initiator or a heat cure catalyst, and may not include a moisture adsorbent, an absorbent, a desiccant, and an organic solvent.

The silicon and silicon organic hybrid oligomers are materials that can be used in encapsulant compositions of OLEDs due to their excellent thermal and mechanical properties as well as high transparency and low refractive index. In addition, it is possible to reduce the sensing error of the touch sensor that goes on the encapsulant with low electrical conductivity, and it is possible to apply the encapsulant with a low viscosity on the OLED using inkjet printing technology. This material can be polymerized under the action of a UV cure initiator under a heat cure catalyst. According to one embodiment of the present disclosure, as for the silicone and silicone organic hybrid oligomers, polydimethylsiloxane (PDMS), polyphenylsilsesquioxane (PPSQ), methylphenylsilicone (MPS), polyhedral oligomeric silsesquioxane (POSS), vinyl-terminated silicone resin (VTSR), etc., may be used, but are not limited thereto.

The UV cure initiator is not particularly limited as long as it can induce polymerization of the aforementioned silicone and silicone organic hybrid oligomers. According to one embodiment of the present disclosure, the UV cure initiator may be, for example, a cationic photopolymerization initiator, a photo-radical polymerization initiator, etc.

Examples of the heat cure catalyst include imidazole derivatives such as imidazole, 2-methylimidazole, 2-ethylimidazole, 2-ethyl-4-methylimidazole, 2-phenylimidazole, 4-phenylimidazole, 1-cyanoethyl-2-phenylimidazole and 1-(2-cyanoethyl)-2-ethyl-4-methylimidazole; amines such as dicyandiamide, benzyldimethylamine, 4-(dimethylamino)-N,N-dimethylbenzylamine, 4-methoxy-N,N-dimethylbenzylamine, 4-methyl-N,N-dimethylbenzylamine; hydrazine compounds such as adipic acid dihydrazide and sebacic acid dihydrazide; phosphorus compounds, such as a triphenylphosphine, etc. In addition, guanamine, acetoguanamine, benzoguanamine, melamine, and S-triazine derivatives such as 2,4-diamino-6-methacryloyloxyethyl-S-triazine, 2-vinyl-2,4-diamino-S-triazine, 2-vinyl-4,6-diamino-S-triazine·isocyanuric acid adduct, 2,4-diamino-6-methacryloyloxyethyl-S-triazine isocyanuric acid adduct, etc., may be used, but are not limited thereto.

The encapsulant composition of the present disclosure may not include a moisture adsorbent, an absorbent, a desiccant, and an organic solvent. The moisture adsorbent, absorbent, desiccant, and organic solvent may refer to additives commonly used in the art to lower the moisture content of encapsulant compositions, and examples of the moisture adsorbent include calcium oxide (CaO), barium oxide (BaO), zeolite, silica gel, molecular sieve, montmorillonite, sodium hydroxide (NaOH), potassium hydroxide (KOH), etc., and examples of the organic solvent include glycol-based organic solvent, etc.

Conventional encapsulant compositions generally include additives such as moisture adsorbents, absorbents, desiccants, and organic solvents in order to effectively lower the moisture content in the dehydration process, and these additives have been appropriately removed through a filtration process after dehydration. However, it is impossible to completely remove the additives already included in the encapsulant composition, and therefore, the encapsulant composition before being supplied to the thin film encapsulation process contains a small amount of residual additives or requires filtering and filtration processes. When the OLED is encapsulated using such a low-purity encapsulant composition, impurities may escape during the production process and a dead cell may be created so that the OLED pixels do not operate, thereby making the protection of the OLED from moisture and oxygen to be limited. Accordingly, the present disclosure has an advantage in that it is possible to provide an encapsulant composition having a moisture content of 100 ppm or less without using additives such as a moisture adsorbent, an absorbent, a desiccant, and an organic solvent.

The encapsulant composition according to the present disclosure may further comprise an epoxy compound. Examples of the epoxy compound include 3-glycidoxypropyltrimethoxysilane, 3-glycidoxypropylmethyldimethoxysilane, 3-glycidoxypropyltriethoxysilane, 3-glycidoxypropylmethyldiethoxysilane, 2-(3,4-epoxycyclohexyl)ethyltrimethoxysilane, 2-(3,4-epoxycyclohexyl)ethylmethyldimethoxysilane, 2-(3,4-epoxycyclohexyl)ethyltriethoxysilane, etc., but is not limited thereto.

According to one embodiment of the present disclosure, the encapsulant composition of the present disclosure may further include other components such as a surfactant, a photosensitizer, an antioxidant, a UV stabilizer, etc., in an appropriate amount within a range that does not impair the object of the present disclosure.

The encapsulant composition of the present disclosure may be for encapsulation of an OLED. The cured product of the present disclosure may be obtained by irradiating UV to the aforementioned encapsulant composition, and the OLED of the present disclosure may be sealed with the cured material. The encapsulant composition may be applied on an OLED by a method known in the art, such as a deposition method, a coating method, inkjet printing, etc., and may be cured by ultraviolet irradiation to form a cured product that encapsulates the OLED.

Hereinafter, the apparatus used in the manufacturing method of the present disclosure will be described.

The apparatus of the present disclosure may be operated in a closed system. The drying apparatus is a closed system that prevents infiltration of air from the atmosphere and controls the release of suffocating gases to designated vent lines. The drying unit is designed to perform filtering as well as drying. In some cases, drying and filtration must be carried out separately. Herein, the dried product should be stored without re-contamination of moisture during filtration or before packaging. A closed system is possible to essentially maintain the quality of the moisture content.

Hereinafter, embodiments of the apparatus of the present disclosure will be described with reference to the figures.

In the present disclosure, the singular also includes the plural unless specifically stated otherwise in the text. For example, the sieve tray used herein may mean at least one sieve tray of the first sieve tray and the second sieve tray, and the sparger may mean at least one sparger of the first sparger and the second sparger.

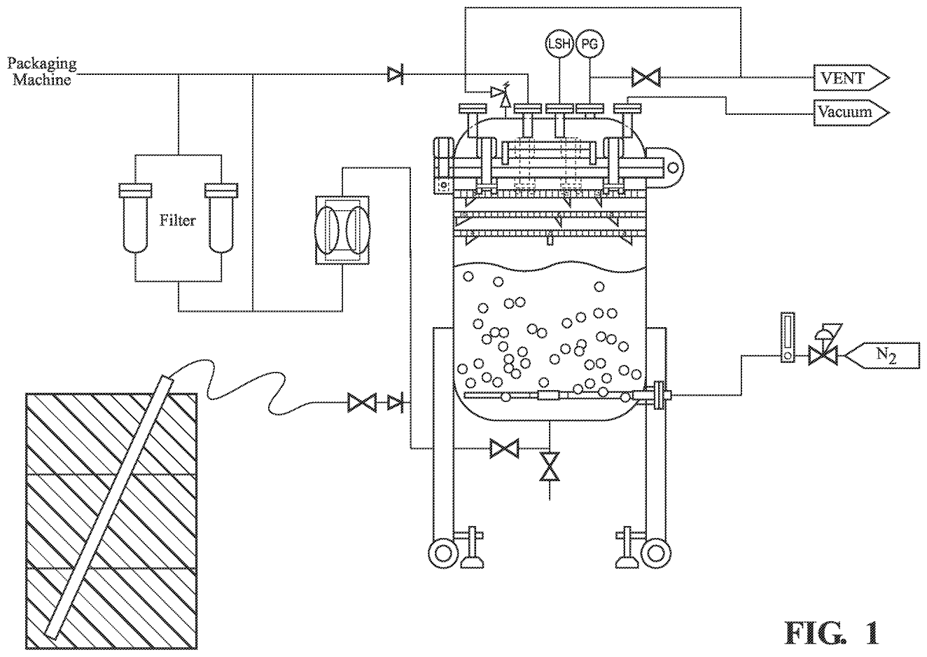

FIG. 1 is a diagram schematically illustrating the apparatus according to an embodiment of the present disclosure.

Referring to FIG. 1, the apparatus according to one embodiment of the present disclosure includes a drying vessel, an inlet for an encapsulant composition, an inert gas supply source, a vent, a sparger, a sieve tray, a transfer tube, etc.

The drying vessel is provided to serve as a reaction tank in which the dehydration process of the encapsulant composition proceeds, and may be configured as a closed system to block the penetration of moisture in the air. The entry and exit of the encapsulant composition, moisture collected in the encapsulant composition, and inert gas may be controlled through an inlet for the encapsulant composition connected to the drying vessel, an inert gas supply source, a sparger, and a vent.

The drying vessel may be a pressurized vessel. The drying performance is proportional to the flow rate of the drying gas and the convergence value is determined by the flow rate. Therefore, since the flow rate must be adjusted as necessary, the drying vessel may be a pressurized vessel for intrinsic safety. Assuming that the main supply pressure of the inert gas is 7 bar, the design pressure can be higher than 10 bar. The drying gas is an inert gas of the present disclosure, which may be nitrogen, etc.

The size of the drying vessel may be set in consideration of the volume of the product, the space of the sieve tray, and the fact that a blank space is required since a lot of bubbles are generated and can go to the upper vent line if bubbles are continuously bubbled. However, if the blank space is too large, it may be detrimental to the performance of the sieve tray.

The inlet for the encapsulant composition is provided to supply the encapsulant composition into the drying vessel, and may be located at an upper portion of the drying vessel.

The inert gas of the present disclosure is supplied from an inert gas supply source and injected into the drying vessel through a sparger, and a vent is disposed at the top of the drying vessel to discharge the inert gas from the drying vessel. The vent line is designed to conveniently control the gas flow with a valve. In the initial design stage, the vent line size can be set to flow inert gas at, for example, 50 to 200 NL/min.

The drying vessel includes a sparger inserted into the pooled liquid encapsulant composition at the bottom and a sieve tray positioned on the pooled liquid encapsulant composition.

The sparger is a nozzle for supplying an inert gas to the drying vessel. Herein, the smaller the bubble size, the wider the contact area between liquid and gas for mass transfer. Thus, the sparger may be a sintered metal filter with a pore size of 100 μm or less. According to one embodiment of the present disclosure, the pore size may be 0.2 to 100 μm. When the inert gas is injected into the encapsulant composition through the sintered metal filter including the one or more pores, the contact area between the encapsulant composition and the inert gas increases, thereby further improving the dehydration effect of the encapsulant composition. The number and length of spargers are adjusted to minimize the dead volume of the vessel. Volume per sparger size may affect drying performance. The shape of the sparger may also vary and may have a circular shape, a bottom shape, etc., but is not limited thereto.

The sieve tray includes one or more openings, and increases a contact area between the encapsulant composition and the inert gas to improve mass transfer efficiency between the liquid and gas. Moisture in the encapsulant composition of the present disclosure is transferred from the liquid to gas, and then the moisture-containing gas moves upward. Meanwhile, the gas passes through the air layer at the liquid surface and goes out to the vent line. Herein, the recycled liquid drops from the top to the bottom of the drying vessel, and the gas rises through the same opening of the sieve tray and contact each other while flowing backward from sieve tray to sieve tray. Mass transfer occurs by contact of the liquid with gas. This mass transfer is effective for the gas to contain and transport moisture up to the vent line. It is recommended to use all openings in the sieve tray to maximize mass transfer efficiency. The size of the opening of the sieve tray may vary depending on the flow rate and viscosity of the liquid to be pooled.

Herein, a return line disposed between the sieve tray and the first connection may be further included to uniformly distribute the supplied encapsulant composition over the sieve tray.

In addition, the drying vessel includes a transfer tube including a first connection connected to an upper portion of the drying vessel and a second connection connected to a lower portion of the drying vessel.

The transfer tube is configured to suck the pooled liquid encapsulant composition via the second connection and supply the sucked liquid encapsulant composition to the first connection through the transfer tube, such that the supplied liquid encapsulant composition is returned to the pooled encapsulant composition from the first connection through the sieve trays.

The transfer tube may further include a pump for circulating the liquid encapsulant composition. The pump raises and circulates the encapsulant composition supplied to the lower portion of the drying vessel to the upper portion of the drying vessel, and may be located outside the drying vessel.

In addition, the apparatus of the present disclosure may include an agitator, a level switch, a vacuum pump, a recycle pump, a filter, etc.

Once foam is created and grown in the manufacturing method of the present disclosure, it moves rapidly through the vent line, and since the foam contains a large amount of liquid, it may cause many losses and process problems including safety problems. Thus, an agitator and level switch may be used to break the foam, prevent foam growth, or prevent liquid dripping from above through recycling from growing foam. The height of the agitator may be the height of the upper surface of the liquid encapsulant composition of the present disclosure to easily break the foam.

A vacuum pump can be used, as vacuum not only accelerates the mass transfer, but also breaks the foam.

The recycle pump may serve several roles. First, liquid is circulated from the bottom of the drying vessel to the top of the drying vessel for mass transfer in the sieve tray. Second, it circulates the liquid for filtering. The liquid must be recirculated for several hours to filter out dust from the entire volume of the liquid. Third, the pump serves to load the liquid from the drum into the drying vessel. Lastly, it serves to supply the purified and dried product into a packaging machine.

The manufacturing method of the present disclosure includes supplying an inert gas from the inert gas supply source through the sparger into the liquid encapsulant composition; sucking the liquid encapsulant composition in the drying vessel from the second connection and supplying the sucked liquid encapsulating composition to the first connection through the transfer tube; and returning the supplied liquid encapsulant composition from the first connection to the pooled liquid encapsulant composition through the sieve trays.

The specific description of each step is consistent with the description of the apparatus.

The manufacturing method of the present disclosure may not comprise a heating process.

Conventionally, it was common to heat and dry the encapsulant composition. However, when the encapsulant composition is heated at a temperature of 40 °C or higher, the photopolymerization initiator included in the encapsulant composition is activated by heat, thereby increasing the viscosity of the encapsulant composition. Accordingly, the manufacturing method of the present disclosure may prevent activation of the photopolymerization initiator in the drying process of the encapsulant composition by not comprising a heating process.

The present disclosure controls the moisture content of the encapsulant composition to 100 ppm or less as described above before being supplied to the known thin film process, even when the cured product of the encapsulant composition is directly deposited or coated on the OLED to seal the OLED, chemical damage to the OLED may be prevented, and thus the reliability of the OLED may be improved.

Meanwhile, silicone resin is a material superior to acrylate-based resin in thermal stability, chemical stability, flexibility, electrical insulation, etc. When an OLED is encapsulated using an encapsulant composition containing a silicone resin, an OLED of more excellent durability and capable of operating without error with a small coating amount may be manufactured. Accordingly, the present disclosure lowers the moisture content of the encapsulant composition containing a silicone resin to 100 ppm or less, so that the OLED encapsulated using the encapsulant composition of the present disclosure may exhibit excellent effects in light output, mechanical properties as well as reliability.

Hereinafter, specific embodiments of a method for manufacturing an encapsulant composition having a moisture content of 100 ppm or less with use of an apparatus, and apparatus according to the present disclosure will be described. However, the following examples are only for explaining the present disclosure for detailed understanding of the present disclosure, and the present disclosure is not limited to the following examples.

### Examples

An ultraviolet curable organopolysiloxane composition for an OLED was dried. Specifically, the apparatus and operating conditions used in the examples are as follows.

The apparatus for dehydrating the encapsulant composition includes a drying vessel, an inlet for the encapsulant composition, a vent, a pump, a sparger, and a sieve tray. The structure and operation of the dehydration apparatus and the manufacturing method of the dehydrated encapsulant composition are the same as those described above, and thus overlapping descriptions are omitted. Hereinafter, the details related to the specific structure of the device and the result of the moisture content of the encapsulant composition dehydrated by the apparatus will be described.

The encapsulant composition before dehydration was injected in an amount of 10 kg from the drum to the upper line of the drying vessel through a pipe connected to the pump and transferred to the drying vessel having a volume of 20 L. The encapsulant composition transferred to the drying vessel was continuously circulated while moving back to the top of the drying vessel through the pump. Nitrogen was injected through a sparger located at the bottom of the drying vessel.

The second connection in the drying vessel is positioned on the lower side to promote mixing with nitrogen through a smooth flow of the encapsulant composition in the drying vessel. The injected encapsulant composition was injected into the center of the sieve tray to ensure good dispersion. The apparatus used comprises one sparger of a Ø25.4 mm×214 mm sintered filter with pores of 1 micron size. Nitrogen as a dry gas was injected for about 5 hours at a flow rate of 90 NL/min.

Three sieve trays were placed on the upper portion of the drying vessel, each containing 86 openings with a diameter of 12.7 mm, and the distance between each opening was constant. The distance between the sieve trays is 38 mm, and the distance between the top of the drying vessel and the sieve tray is also 38 mm. In the two adjacent sieve trays, each sieve tray was configured to increase contact between the encapsulant composition and nitrogen gas by not allowing the openings to be located on the same line with respect to the vertical direction. Through mass transfer while passing through the encapsulant, the gas containing moisture contacts again with the falling recirculated encapsulant composition in the sieve tray, and through this process, the nitrogen gas containing moisture flows out of the drying vessel through the vent line.

An ultraviolet curable organopolysiloxane composition having the composition (part by mass) of Table 1 below was dried using the aforementioned apparatus and manufacturing method.

Component (A) is (EpMe₂Si)₂O (where “Ep” is epoxy and “Me” is methyl)

Component (B) is EpMeSi(OSiMe₃)₂

Component (C) is a combination of 96 parts component (X) to 4 parts component (Y) (where component (X) is 4-isopropyl-4′-methyldiphenyliodoniumtetrakis(pentafluorophenyl) borate and component (Y) is 2-isopropylthioxanthone)

TABLE 1

| Component | Example 1 | Example 2 | Example 3 |
|---|---|---|---|
| (A) | 5.0 | 30.0 | 60.0 |
| (B) | 93.9 | 68.9 | 38.9 |
| (C) | 1.1 | 1.1 | 1.1 |

As a result of drying the UV curable organopolysiloxane compositions of Examples 1 to 3, the moisture contents were 64.8 ppm, 62.7 ppm, and 57.9 ppm, respectively.

1. A method for manufacturing an encapsulant composition having a moisture content of 100 ppm or less with use of an apparatus comprising: a drying vessel including therein a sparger being inserted into a liquid encapsulant composition pooled at a lower side of the drying vessel and sieve trays positioned above the pooled liquid encapsulant composition; an inert gas supply source supplying inert gas to the drying vessel; and a transfer tube including a first connection connected to an upper portion of the drying vessel and a second connection connected to a lower portion of the drying vessel, the method comprising:
supplying the inert gas from the inert gas supply source through the sparger into the liquid encapsulant composition;
sucking the liquid encapsulant composition in the drying vessel from the second connection and supplying the sucked liquid encapsulant composition to the first connection through the transfer tube; and
returning the supplied liquid encapsulant composition from the first connection to the pooled encapsulant composition through the sieve trays.

2. The method according to claim 1, wherein the encapsulant composition comprises silicone and silicone organic hybrid oligomers and a UV cure initiator or a heat cure catalyst, and is free of a moisture adsorbent, an absorbent, a desiccant, and an organic solvent.

3. The method according to claim 1, wherein the sparger is a sintered metal filter comprising pores, and wherein the size of the pores of the sintered metal filter is 100 μm or less.

4. The method according to claim 1, wherein the method does not comprise a heating process.

5. The method according to claim 1, wherein the drying vessel further comprises a vent disposed at an upper side of the drying vessel for exiting the inert gas from the drying vessel.

6. An encapsulant composition comprising a silicone and silicone organic hybrid oligomers and a UV cure initiator or a heat cure catalyst, wherein the encapsulant composition has a moisture content of 100 ppm or less.

7. An encapsulant composition comprising a silicone and silicone organic hybrid oligomers and a UV cure initiator or a heat cure catalyst, wherein the encapsulant composition has a moisture content of 100 ppm or less, and wherein the encapsulant composition is manufactured by the method according to claim 1.

8. The encapsulant composition according to claim 7, wherein the encapsulant composition is free of a moisture adsorbent, an absorbent, a desiccant, and an organic solvent.

9. The encapsulant composition according to claim 7, wherein the encapsulant composition further comprises an epoxy compound.

10. The encapsulant composition according to claim 7, wherein the encapsulant composition is for encapsulating an organic electroluminescent device.

11. An apparatus for manufacturing an encapsulant composition having a moisture content of 100 ppm or less, the apparatus comprising:
a drying vessel configured to pool a liquid encapsulant composition pooled at a lower side of the drying vessel;
a sparger being inserted into the pooled liquid encapsulant composition;
sieve trays positioned above the pooled liquid encapsulant composition;
an inert gas supply source configured to supply the inert gas to the pooled liquid encapsulant composition in the drying vessel through the sparger; and
a transfer tube including a first connection connected to an upper portion of the drying vessel and a second connection connected to a lower portion of the drying vessel, wherein the transfer tube is configured to suck the pooled liquid encapsulant composition via the second connection and supply the sucked liquid encapsulant composition to the first connection through the transfer tube, such that the supplied liquid encapsulant composition is returned to the pooled encapsulant composition from the first connection through the sieve trays.

12. The apparatus according to claim 11, wherein the sparger is a sintered metal filter comprising pores, and wherein the size of the pores of the sintered metal filter is 100 μm or less.

13. The apparatus according to claim 11, wherein the transfer tube further comprises a pump for circulating the liquid encapsulant composition.

14. The apparatus according to claim 11, further comprising a return line disposed between the first connection to the sieve trays for evenly distributing the supplied encapsulant composition across the sieve trays.

15. The apparatus according to claim 11, wherein the drying vessel further comprises a vent disposed at an upper side of the drying vessel for exiting the inert gas from the drying vessel.
